(19) United States
(12) Patent Application Publication
(10) Pub. No.: US 2026/0079197 A1
(43) Pub. Date: Mar. 19, 2026

(54) TEST APPARATUS AND TEST METHOD

(71) Applicant: ADVANTEST CORPORATION, Tokyo (JP)

(72) Inventor: Hiroki KIMURA, Saitama (JP)

(21) Appl. No.: 19/402,994

(22) Filed: Nov. 27, 2025

Related U.S. Application Data
(63) Continuation of application No. PCT/JP2023/030205, filed on Aug. 22, 2023.

(51) Int. Cl. G01R 31/28; G01R 1/30

(52) U.S. Cl. CPC G01R 31/2879; G01R 1/30; G01R 31/287; G01R 31/2882

(57) ABSTRACT

There is provided a test apparatus including a first power source which outputs a first voltage of predetermined magnitude or a first current of predetermined magnitude; a first switch unit which connects, to the first power source, a connection terminal of a device under test serving as a test target, among connection terminals of a plurality of devices under test; a first measuring unit which measures an electrical characteristic of the device under test serving as the test target in response to the first power source being connected to the device under test serving as the test target; and a second voltage source which outputs a second voltage of predetermined magnitude to a connection terminal of another at least one device under test which is different from the device under test serving as the test target, among the plurality of devices under test.

The contents of the following patent application(s) are incorporated herein by reference: NO. PCT/JP2023/030205 filed in WO on Aug. 22, 2023.

### BACKGROUND

### 1. Technical Field

The present invention relates to a test apparatus and a test method.

### 2. Related Art

Patent documents 1 and 2 describe, in a paragraph 0035, that “the present embodiment uses a measuring means (SMU 20) which measures an electrical characteristic of a DUT 50, another measuring means (an LCR meter 22 or a pulse generator 24) which measures another electrical characteristic of the DUT, and a switching unit 12 (ASU 12P and 12M) which is connected to a control means (a controller 202) and includes a minute current detection means. This switching unit is . . . electrically connected to the DUT 50. In addition, this switching unit 12 is electrically connected to several measuring means via a cable, and switches, based on a control signal from the control means (the controller 202), whether the measuring means or the second measuring means is electrically connected to the element to be measured . . . ”, or the like.

### RELATED ART DOCUMENTS

### Patent Documents

Patent Document 1: Japanese Patent Application Publication No. 2005-300495
Patent Document 2: Japanese Patent Application Publication No. 2010-190768

### BRIEF DESCRIPTION OF THE DRAWINGS

FIG. 1 illustrates a test system 1 according to a first embodiment.

FIG. 2 illustrates an operation of a test apparatus 2.

FIG. 3 illustrates operation waveforms of the test apparatus 2.

FIG. 4 illustrates a test system 1A according to a second embodiment.

FIG. 5 illustrates operation waveforms of a test apparatus 2A.

FIG. 6 illustrates an example of a computer 2200 in which a plurality of aspects of the present invention may be entirely or partially embodied.

### DESCRIPTION OF EXEMPLARY EMBODIMENTS

The present invention will be described below by way of embodiments of the invention, but the embodiments below are not intended to limit the invention according to the claims. In addition, not all combinations of features described in the embodiment are essential to a solution of the invention.

### First Embodiment

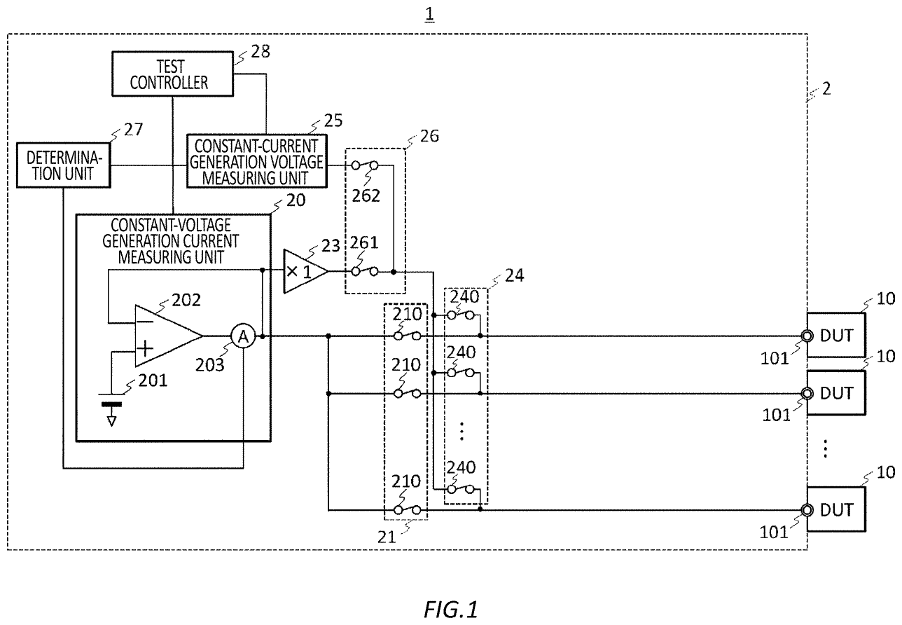

FIG. 1 illustrates a test system 1 according to the present embodiment. The test system 1 includes a plurality of devices under test 10 and a test apparatus 2. Each of the devices under test 10 is depicted as a DUT, or Device Under Test, in the figure.

### (Device Under Test 10)

Each device under test 10 is an electronic device tested by the test apparatus 2. For example, each device under test 10 may be an integrated circuit including a semiconductor, a discrete-type semiconductor element, or another type of device.

Each device under test 10 may include at least one connection terminal 101 connected to the test apparatus 2. Each device under test 10 may further include another connection terminal, which is not shown, connected to a ground voltage.

### (Test Apparatus 2)

The test apparatus 2 tests each device under test 10. The test apparatus 2 may test quality of an electrical static characteristic of each device under test 10 connected thereto in advance. To perform testing, the test apparatus 2 may sequentially switch to any device under test 10 serving as a test target, among the plurality of devices under test 10 (in the present embodiment, n devices under test 10 as an example (note that n is a natural number of two or more)). Order of the devices under test 10 may be set according to their connection positions to the test apparatus 2. When the n devices under test 10 are aligned in a row and connected to the test apparatus 2, a device under test 10 at one end may be a first device under test 10, and a device under test 10 at another end may be an n-th device under test 10.

The test apparatus 2 includes a constant-voltage generation current measuring unit 20, a first switch unit 21, a second voltage source 23, a second switch unit 24, a constant-current generation voltage measuring unit 25, a third switch unit 26, a determination unit 27, and a test controller 28.

### ((Constant-Voltage Generation Current Measuring Unit 20))

The constant-voltage generation current measuring unit 20 measures a value corresponding to a current which flows through the device under test 10 serving as the test target in response to applying a constant voltage to this device under test 10. The constant-voltage generation current measuring unit 20 includes a first voltage source 201, an amplifier 202, and a current sensor 203.

### (((First Voltage Source 201)))

The first voltage source 201 is an example of a first power source, and outputs a first voltage of predetermined magnitude. The first voltage source 201 may supply the first voltage to a non-inverting input terminal of the amplifier 202. The first voltage may be a voltage for causing a current to flow through the device under test 10 serving as the test target for performing a measurement, that is, a voltage for the measurement. The magnitude of the first voltage may be set arbitrarily according to a characteristic of the device under test 10. In the present figure, the first voltage source 201 is illustrated as a battery, as an example, but it may be another device, such as a rectifier or a converter.

### (((Amplifier 202)))

The amplifier 202 is provided between the first voltage source 201 and the current sensor 203 to constitute a voltage follower circuit. An output terminal of the amplifier 202 is connected to the current sensor 203, and also to an inverting input terminal via the current sensor 203. The amplifier 202 may have a gain of 1 (0 dB), and may output the first voltage output from the first voltage source 201 from its output terminal.

### (((Current Sensor 203)))

The current sensor 203 is provided between the output terminal of the amplifier 202 and the first switch unit 21. The current sensor 203 is an example of a first measuring unit, and measures an electrical characteristic of the device under test 10 serving as the test target, in response to the first voltage source 201 being connected to this device under test 10. The current sensor 203 may measure the value corresponding to the current which flows through the device under test 10 serving as the test target in response to the first voltage source 201 applying the first voltage. In the present embodiment, the current sensor 203 measures, as an example, a current itself flowing between the output terminal of the amplifier 202 and the first switch unit 21, but it may perform a measurement at another location, or it may measure another value corresponding to the current, such as a voltage generated across a resistance corresponding to the current, or the like. The current sensor 203 may supply a measurement value to the determination unit 27.

### ((First Switch Unit 21))

The first switch unit 21 is provided between the constant-voltage generation current measuring unit 20 and the n devices under test 10. The first switch unit 21 connects, with the first voltage source 201, the connection terminal 101 of the device under test 10 serving as the test target among connection terminals 101 of the n devices under test 10. The first switch unit 21 may alternately connect the connection terminal 101 of the device under test 10 serving as the test target with the first voltage source 201. The first switch unit 21 may include n switches 210, each of which includes one end connected to the output terminal of the amplifier 202 in the constant-voltage generation current measuring unit 20, and another end connected to the connection terminal 101 of one of the n devices under test 10. Another end of an N-th switch 210 among the n switches 210 (note that N is a natural number which satisfies 1≤N≤n) may be connected with a connection terminal 101 of an N-th device under test 10. Each switch 210 may be controlled by the test controller 28 described below.

### ((Second Voltage Source 23))

The second voltage source 23 outputs a second voltage of predetermined magnitude. The second voltage source 23 may output the second voltage of the predetermined magnitude to the connection terminal 101 of another at least one device under test 10, which is different from the device under test 10 serving as the test target, among the n devices under test 10. The second voltage source 23 according to the present embodiment may cooperate with the second switch unit 24 to output the second voltage to the at least one device under test 10 which is different from the test target.

The device under test 10 to which the second voltage is output may include the device under test 10 among the n devices under test 10 which is to be measured by the current sensor 203 subsequent to the device under test 10 serving as the test target, or may include the device under test 10 which was measured before the device under test 10 serving as the test target, or may include the device under test 10 which is arranged near the device under test 10 serving as the test target. In the present embodiment, the device under test 10 to which the second voltage is output may be, as an example, each of n−1 devices under test 10 which is different from the device under test 10 serving as the test target, among the n devices under test 10.

The second voltage source 23 may output the second voltage concurrently with the measurement by the current sensor 203, or may output the voltage over a measurement period of the current sensor 203. The second voltage source 23 may be an amplifier which amplifies the first voltage output from the first voltage source 201 with a preset gain, and may output a voltage concurrently with a voltage output of the first voltage source 201. Illustration is simplified in FIG. 1, but the amplifier as the second voltage source 23 may be connected to the amplifier 202 of the constant-voltage generation current measuring unit 20 to constitute a voltage follower circuit, and its gain may be 1 (0 dB).

The second voltage may be a voltage for causing a current to flow through the device under test 10 which is different from the test target, to settle this device under test 10 at a standby potential, that is, a voltage for standby. The second voltage may be a voltage closer to the first voltage than to the ground voltage of the n devices under test 10. In the present embodiment, it may be a voltage of same magnitude as the first voltage, as an example.

A current path through which a current flows in the test apparatus 2 due to the voltage from the second voltage source 23 may be insulated from a current path through which a current flows in the test apparatus 2 due to the voltage from the first voltage source 201. In the present embodiment, as an example, since the second voltage source 23 is an amplifier, its input side and its output side are insulated. In addition, the current path between the second voltage source 23 and each device under test 10 which is not the test target, and the current path between the first voltage source 201 and the device under test 10 serving as the test target are separate paths without a common portion with each other and insulated.

### ((Second Switch Unit 24))

The second switch unit 24 is provided between the second voltage source 23 and the n devices under test 10. When the constant-voltage generation current measuring unit 20 performs a measurement, the second switch unit 24 selectively connects the second voltage source 23 to the connection terminal 101 of the device under test 10 which is different from the test target tested by the constant-voltage generation current measuring unit 20. In the present embodiment, as an example, the second switch unit 24 may connect the connection terminal 101 of each of the n−1 devices under test 10, which are not the test target, to the second voltage source.

When the constant-current generation voltage measuring unit 25 described below performs a measurement, the second switch unit 24 may connect the constant-current generation voltage measuring unit 25 to the connection terminal 101 of the device under test 10 serving as the test target tested by the constant-current generation voltage measuring unit 25. When the constant-current generation voltage measuring unit 25 performs the measurement, the second switch unit 24 may alternately connect the device under test 10 serving as the test target to the constant-current generation voltage measuring unit 25.

The second switch unit 24 may include n switches 240, each of which includes one end connected to the second voltage source 23 and another end connected to the connection terminal 101 of one of the n devices under test 10. Among the n switches 240, another end of an N-th switch 240 may be connected to the connection terminal 101 of the N-th device under test 10. Each switch 240 may be controlled by the test controller 28.

Wiring from the N-th switch 240 in the second switch unit 24 to the N-th device under test 10 and wiring from the N-th switch 210 in the first switch unit 21 to the N-th device under test 10 may include a common wiring portion. The common wiring portion may be provided with a noise removal filter, such as a smoothing capacitor. In addition, a board-shaped interface may be provided between the n devices under test 10 and the n switches 210 and 240 to connect the test apparatus 2 with each device under test 10.

### ((Constant-Current Generation Voltage Measuring Unit 25))

The constant-current generation voltage measuring unit 25 is an example of a second measuring unit, and connected between the second voltage source 23 and the second switch unit 24. The constant-current generation voltage measuring unit 25 measures a value corresponding to a voltage generated in the device under test 10 serving as the test target, in response to a current of predetermined magnitude flowing through this device under test 10. The constant-current generation voltage measuring unit 25 may perform a measurement at a different timing from a measurement timing of the current sensor 203, and may perform a measurement in a state where the device under test 10 serving as the test target tested by the constant-current generation voltage measuring unit 25 and the constant-current generation voltage measuring unit 25 are connected by the second switch unit 24. The current of the predetermined magnitude may be set arbitrarily according to the characteristic of the device under test 10. The constant-current generation voltage measuring unit 25 may include a current source not shown, which causes a constant current to flow through the device under test 10 serving as the test target via the second switch unit 24. The constant-current generation voltage measuring unit 25 may include a sensor not shown, as an example, a voltage sensor, which measures a value corresponding to the voltage generated in the device under test 10 serving as the test target according to the current from the current source, and supplies the value to the determination unit 27. The constant-current generation voltage measuring unit 25 may measure not the voltage itself generated in the device under test 10 serving as the test target, but another value corresponding to the voltage, such as a current caused to flow according to the voltage, or the like.

### ((Third Switch Unit 26))

The third switch unit 26 is provided between the second voltage source 23 and the constant-current generation voltage measuring unit 25, and the second switch unit 24. The third switch unit 26 includes a switch 261 provided between the constant-current generation voltage measuring unit 25 and the second switch unit 24, and a switch 262 provided between the second voltage source 23 and the second switch unit 24. The switch 261 may be turned on when the constant-voltage generation current measuring unit 20 performs a measurement, that is, when the current sensor 203 performs a measurement, and the switch 262 may be turned on when the constant-current generation voltage measuring unit 25 performs a measurement.

### ((Determination Unit 27))

The determination unit 27 determines quality of the device under test 10 serving as the test target, based on a measurement result from the constant-voltage generation current measuring unit 20. The determination unit 27 according to the present embodiment may determine the quality of the device under test 10 serving as the test target, based on the measurement result from the constant-voltage generation current measuring unit 20 and the constant-current generation voltage measuring unit 25. As an example, in a case where the device under test 10 serving as the test target is determined to be normal based on the measurement result from the constant-voltage generation current measuring unit 20, and the device under test 10 serving as the test target is determined to be normal based on the measurement result from the constant-current generation voltage measuring unit 25, the determination unit 27 may determine this device under test 10 to be acceptable, and may determine the device under test 10 to be defective in another case. The determination unit 27 may determine the quality of the device under test 10 only based on the measurement result from the constant-voltage generation current measuring unit 20.

### ((Test Controller 28))

The test controller 28 controls each unit of the test apparatus 2 and tests each device under test 10. For example, the test controller 28 may cause the current sensor 203 to measure the current flowing through the device under test 10 serving as the test target, while causing the first voltage source 201 and the second voltage source 23 to output voltages, and switching, by using the first switch unit 21 and the second switch unit 24, a connection state between each of the first voltage source 201 and the second voltage source 23, and each device under test 10. The test controller 28 may cause the constant-current generation voltage measuring unit 25 to measure the voltage generated in the device under test 10 serving as the test target, while causing the constant-current generation voltage measuring unit 25 to output the current and switching, by using the second switch unit 24, a connection state between the constant-current generation voltage measuring unit 25 and each device under test 10. The test controller 28 may be achieved by software executed by a processor, or the like.

(Effect Obtained from Test Apparatus 2)

According to the test apparatus 2 described above, since the second voltage is output to the connection terminal 101 of the device under test 10 which is different from the test target, it is possible to settle the device under test 10 which is different from the test target at a predetermined potential and put it in a standby state for testing. For example, when the device under test 10 serving as the test target, which is defective, is applied with the first voltage and tested, an electric charge may move through an inter-wiring capacitance, between wiring from the first switch unit 21 to the device under test 10 serving as the test target and wiring from the first switch unit 21 to the device under test 10 which is not the test target. Even in such a case, an output of the second voltage can eliminate a movement of the electric charge in advance to lower an impedance of the wiring leading to the device under test 10 which is different from the test target, make it less susceptible to a disturbance and inter-wiring coupling, and put the device under test 10 which is different from the test target in the standby state for testing in advance. In addition, when the device under test 10 is a capacitive load and it is necessary to charge the device under test 10 with an electric charge for testing, the output of the second voltage can pre-charge the device under test 10 which is different from the test target with an electric charge and put it in the standby state for testing. Thus, a test on each device under test 10 can be started earlier.

In addition, since the current path from the second voltage source 23 to the device under test 10 which is different from the test target, and the current path from the first voltage source 201 to the device under test 10 serving as the test target are separate paths from each other, even when the current sensor 203 measures a value corresponding to a minute current, a non-minute current can flow through the current path from the second voltage source 23 to the device under test 10 which is different from the test target. Thus, each device under test 10 can be put into the standby state for testing at an earlier time.

In addition, since the second voltage is output concurrently with the measurement by the current sensor 203, the device under test 10 which is different from the test target can be put into the standby state for testing during a test on the device under test 10 serving as the test target. Thus, it is ensured that the test on each device under test 10 can be started earlier.

In addition, since the second voltage source 23 is selectively connected to each connection terminal 101 of the at least one device under test 10 which is different from the test target, it is possible to apply the second voltage to the device under test 10 which is different from the test target, while preventing the second voltage from being applied to the device under test 10 serving as the test target.

In addition, the device under test 10 to which the second voltage is applied includes the device under test 10 which is to be measured subsequent to the device under test 10 serving as the test target. Thus, it is possible to put the device under test 10, which is to be measured next, into the standby state for testing, and start a test on this device under test 10 earlier.

In addition, since the constant-current generation voltage measuring unit 25 is connected between the second voltage source 23 and the second switch unit 24, a path between the constant-current generation voltage measuring unit 25 and each device under test and a path between the second voltage source 23 and each device under test 10 can be made common. In addition, by connecting the second voltage source 23 in a path between the constant-current generation voltage measuring unit 25 and each device under test 10, the test apparatus 2 can be formed.

In addition, since the second voltage source 23 is an amplifier which amplifies the first voltage from the first voltage source 201, the input side and the output side of the second voltage source 23 can be insulated. Thus, it is possible to prevent a reduction in measurement accuracy caused by a current from the first voltage source 201 flowing to a side of the second voltage source 23.

In addition, since the second voltage is a voltage of the same magnitude as the first voltage, the device under test 10 which is different from the test target can be put into the standby state which allows immediate testing.

In addition, since the second voltage is a voltage closer to the first voltage than to the ground voltage of the device under test 10, it is ensured that the device under test 10 which is different from the test target can be put into the standby state for testing.

### (Operation of Test Apparatus 2)

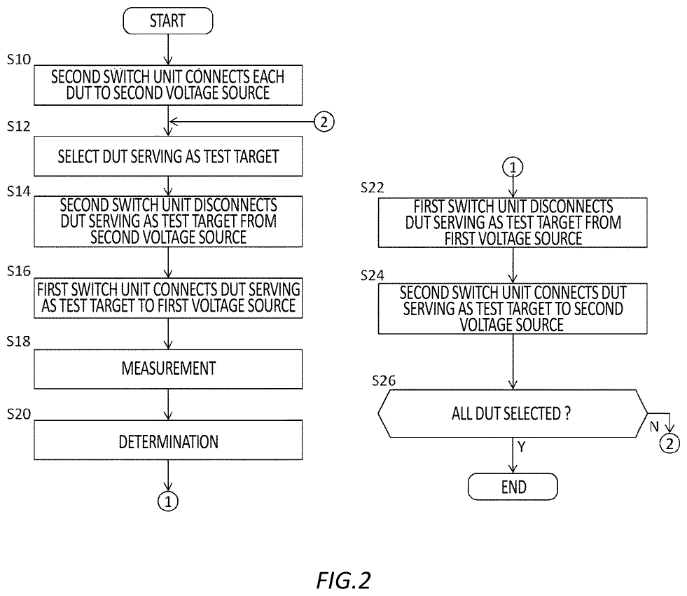

FIG. 2 illustrates an operation of the test apparatus 2. The present figure illustrates an operation related to a measurement by the constant-voltage generation current measuring unit 20 among operations of the test apparatus 2. The test apparatus 2 may test each device under test 10 by performing a process of steps S10 to S26. In the present operation, the first voltage source 201 and the second voltage source may continue outputting voltages.

In the step S10, the second switch unit 24 connects the second voltage source 23 to the connection terminal 101 of the another at least one device under test 10 (in the present embodiment, each device under test 10, as an example) which is different from the device under test 10 serving as the test target. Thus, the second voltage (in the present embodiment, a voltage of the same magnitude as the first voltage, as an example) may be output to the connection terminal 101 of each device under test 10.

In a step S12, the test controller 28 selects any of the n devices under test 10 as the device under test 10 serving as the test target. For each process of the step S12, the test controller 28 may select a different device under test 10, or may select the first device under test 10 to the n-th device under test 10 sequentially.

In a step S14, the second switch unit 24 disconnects the connection terminal 101 of the device under test 10 serving as the test target from the second voltage source 23. Thus, the second voltage source 23 may be connected to the connection terminal 101 of the another at least one device under test 10 (in the present embodiment, each device under test 10 which is different from the test target, as an example) which is different from the device under test 10 serving as the test target, and the second voltage (in the present embodiment, a voltage of the same magnitude as the first voltage, as an example) may be output to the connection terminal 101 of the device under test 10 which is different from the test target.

In a step S16, the first switch unit 21 connects the first voltage source 201 with the connection terminal 101 of the device under test 10 serving as the test target. Thus, the first voltage may be output to the connection terminal 101 of the device under test 10 serving as the test target. The process of the step S16 may be performed simultaneously with the process of the step S14.

In a step S18, the current sensor 203 measures the electrical characteristic of this device under test 10 (in the present embodiment, the current flowing through the device under test 10 serving as the test target, as an example), in response to the first voltage source 201 being connected to the device under test 10 serving as the test target.

In a step S20, the determination unit 27 determines the quality of the device under test 10 serving as the test target, based on the measurement result from the current sensor 203. The determination unit 27 may determine the device under test 10 to be acceptable in response to magnitude of a measured current being within a reference range, or may determine the device under test 10 to be defective in response to the magnitude of the measured current being outside the reference range. The determination unit 27 may determine, in response to a speed of change in a value of the measurement result from the current sensor 203 not falling below a reference value, within a reference time after the first voltage source 201 is connected to the device under test 10 serving as the test target, that is, within the reference time after the process of the step S16 is performed, that the device under test 10 serving as the test target is defective. Thus, the device under test 10 serving as the test target may be determined to be defective in response to a current flowing through this device under test 10 being unstable. The reference time may be shorter than time required for a potential of the device under test 10 serving as the test target to become stable after the first voltage source 201 applies a voltage to this device under test 10 when the voltage from the second voltage source 23 is not applied to the device under test 10 which is different from the test target.

In a step S22, the first switch unit 21 disconnects the connection terminal 101 of the device under test 10 serving as the test target from the first voltage source 201.

In a step S24, the second switch unit 24 connects the second voltage source 23 with the connection terminal 101 of the device under test 10 serving as the test target. Thus, the second voltage may be output to the connection terminal 101 of each device under test 10. The process of the step S24 may be performed simultaneously with the process of the step S22.

In a step S26, the test controller 28 determines whether or not all of the n devices under test 10 are selected in the step S12. When it is determined that not all of the devices under test 10 are selected (the step S26; No), the process may proceed to the step S12. When it is determined that all of the devices under test 10 are selected (the step S26; Yes), the operation may end.

According to the operation described above, the device under test 10 serving as the test target is determined to be defective in response to the speed of the change in the value of the measurement result not falling below the reference value within the reference time after the first voltage source 201 is connected to this device under test 10 serving as the test target. Thus, the device under test 10 serving as the test target can be determined to be defective at a timing when the reference time has elapsed, without a need for waiting until the value of the measurement result becomes stable.

### (Operation Waveform)

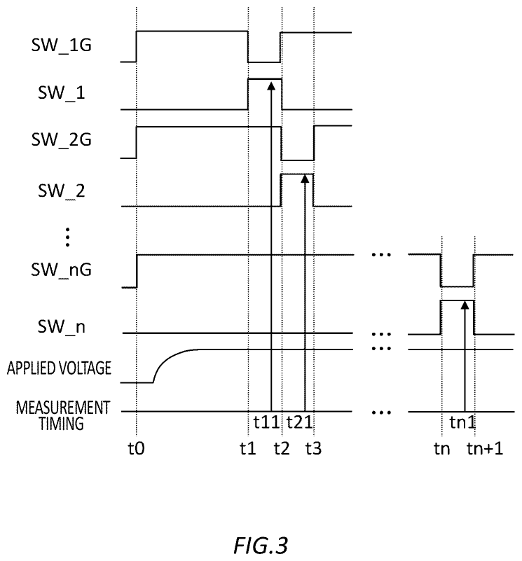

FIG. 3 illustrates operation waveforms of the test apparatus 2. The present figure illustrates waveforms of a measurement operation by the constant-voltage generation current measuring unit 20 among operations of the test apparatus 2. In the figure, a horizontal axis indicates time. Each operation waveform of “SW_1” to “SW_n” indicates a control signal for a first switch 210 to an n-th switch 210 in the first switch unit 21, with a high level indicating on and a low level indicating off. Each operation waveform of “SW_1G” to “SW_nG” indicates a control signal for a first switch 240 to an n-th switch 240 in the second switch unit 24, with a high level indicating on and a low level indicating off. An operation waveform of an “applied voltage” indicates a voltage output from the first voltage source 201 and the second voltage source 23. A measurement timing indicates the measurement timing of the current sensor 203.

At a time point t0, each switch 240 of the second switch unit 24 turns into an ON state to connect each device under test 10 to the second voltage source 23. In addition, the first voltage source 201 and the second voltage source 23 start to output the voltages. Thus, each device under test 10 assumes the standby potential.

At a time point t1, only the first switch 210 becomes an ON state in the first switch unit 21, and only the first switch 240 becomes an OFF state in the second switch unit 24. Thus, in response to the first voltage being applied from the first voltage source 201, a current flows through the device under test 10 serving as the test target (here, the first device under test 10), and the current is measured at a time point t11.

Continuously, at a time point t2, only a second switch 210 becomes an ON state in the first switch unit 21, and only a second switch 240 becomes an OFF state in the second switch unit 24. Thus, in response to the first voltage being applied from the first voltage source 201, a current flows through the device under test 10 serving as the test target (here, a second device under test 10), and the current is measured at a time point t21.

Subsequently, in a similar manner, at a time point tN (note that, here, N is a natural number which satisfies 3≤N≤n), only an N-th switch 210 becomes an ON state in the first switch unit 21, and only an N-th switch 240 becomes an OFF state in the second switch unit 24. Thus, in response to the first voltage being applied from the first voltage source 201, a current flows through the device under test 10 serving as the test target (here, the N-th device under test 10), and the current is measured at a time point tN1.

Although in the first embodiment described above, the test apparatus 2 is described as including the constant-current generation voltage measuring unit 25, the third switch unit 26, the determination unit 27, and the test controller 28, it may not include any of these. For example, the determination unit 27 or the test controller 28 may be provided outside the test apparatus 1. When the test apparatus 2 does not include the constant-current generation voltage measuring unit 25, it may not include the third switch unit 26, either.

In addition, although the first switch unit 21 and the second switch unit 24 are described as performing switching such that each device under test 10 is connected to any one of the first voltage source 201 or the second voltage source 23, at least one device under test 10 may be temporarily connected to the first voltage source 201 and the second voltage source 23.

### Second Embodiment

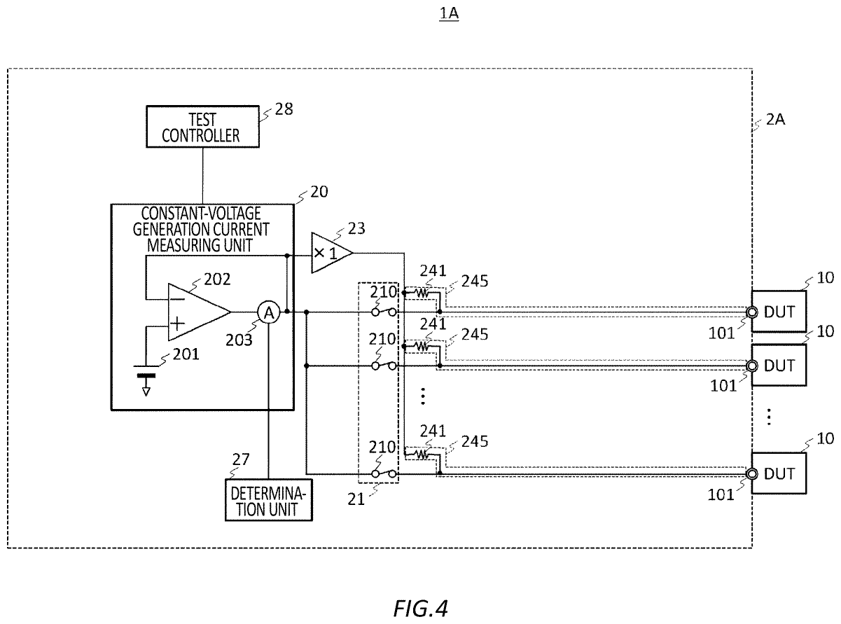

FIG. 4 illustrates a test system 1A according to the present embodiment. In the test system 1A according to the present embodiment, an identical numeral is given to a component which is substantially identical as that of the test system 1 illustrated in FIG. 1, and its description will be omitted.

The test apparatus 2A of the test system 1A includes, instead of the second switch unit 24, a plurality of resistances 241 (in the present embodiment, n resistances 241 as an example) provided in each wiring 245 (in the present embodiment, n wirings 245 as an example) which connects the second voltage source 23 and each connection terminal 101 of the plurality of devices under test 10 (in the present embodiment, n devices under test 10 as an example). When the wiring 245 and a current path from the first voltage source 201 to the device under test 10 have a common portion, each resistance 241 may be provided in a portion in the wiring 245 which is not in the current path from the first voltage source 201 to the device under test 10.

Thus, the second voltage source 23 in the present embodiment may be able to apply the second voltage to each of the n devices under test 10, including the device under test 10 serving as a measurement target. Note that, in the test apparatus 2A according to the present embodiment, since at least one of magnitude of the second voltage relative to the first voltage or magnitude of the resistance 241 is adjusted in advance, a current caused by the voltage from the second voltage source 23 may not flow through the resistance 241 connected to the device under test 10 serving as the test target. As an example, the second voltage may be of a same magnitude as the first voltage. A resistance value of each of the n resistances 241 may be the same as each other.

According to the test apparatus 2A described above, since the resistance 241 is provided in each wiring 245 connecting the second voltage source 23 and the connection terminal 101 of each of the n devices under test 10, each device under test 10 which is different from the test target can be put into the standby state for testing. In addition, unlike the first embodiment, since the device under test 10 which is different from the test target can be settled at the standby potential without switching the second switch unit 24, a component or control for the switching can be omitted. In addition, since it is possible to prevent a current from flowing through the device under test 10 serving as the test target due to the voltage from the second voltage source 23, a reduction in measurement accuracy can be prevented.

The test apparatus 2A described above may perform a measurement by the constant-voltage generation current measuring unit 20 in a similar manner as FIG. 2, except that a process of the steps S10, S14, and S24 is not performed. In addition, in a process of the step S18, the current sensor 203 of the test apparatus 2A may perform a calibration. For example, the current sensor 203 may adjust a measurement value measured in a state where the first switch unit 21 connects the device under test 10 serving as the test target to the first voltage source 201, according to a measurement value measured in a state where the first switch unit 21 does not connect the device under test 10 serving as the test target to the first voltage source 201. Thus, a calibrated accurate measurement value can be acquired. The measurement value of a current in a state where the first switch unit 21 does not connect the device under test 10 serving as the test target to the first voltage source 201 may be a measurement error due to a current flowing through the wiring 245, and may be measured and stored in the test apparatus 2A in advance, before the device under test 10 serving as the test target and the first voltage source 201 are connected, or before starting a test. The current sensor 203 may calculate a calibrated measurement value by subtracting the measurement error from an actual measurement value measured by the current sensor 203 in a state where the first switch unit 21 connects the device under test 10 serving as the test target to the first voltage source 201. The current sensor 203 may cooperate with the test controller 28 to perform a calibration.

### (Operation Waveform)

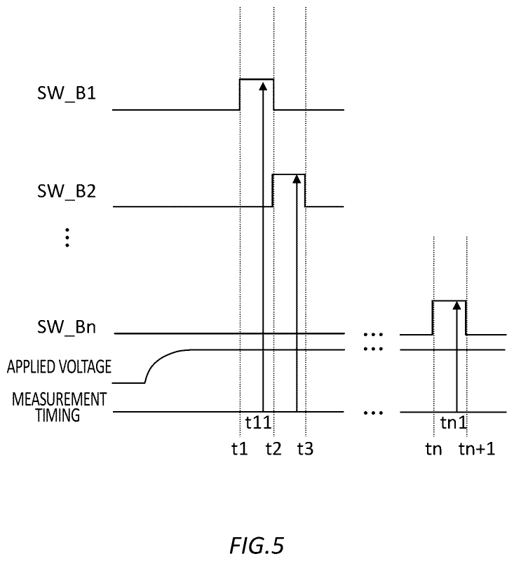

FIG. 5 illustrates operation waveforms of the test apparatus 2A. In the figure, a horizontal axis indicates time. Each operation waveform of “SW_B1” to “SW_Bn” indicates a control signal for a first switch 210 to an n-th switch 210 in the first switch unit 21, with a high level indicating on and a low level indicating off. An operation waveform of an “applied voltage” indicates a voltage output from the first voltage source 201 and the second voltage source 23. A measurement timing indicates the measurement timing of the current sensor 203.

In the present operation, the first voltage source 201 and the second voltage source 23 start to output voltages in advance. Thus, each device under test 10 assumes the standby potential.

At a time point t1, only the first switch 210 becomes an ON state in the first switch unit 21. Thus, in response to the first voltage being applied from the first voltage source 201, a current flows through the device under test 10 serving as the test target (here, the first device under test 10), and the current is measured at a time point t11.

Continuously, at a time point t2, only the second switch 210 becomes an ON state in the first switch unit 21. Thus, in response to the first voltage being applied from the first voltage source 201, a current flows through the device under test 10 serving as the test target (here, a second device under test 10), and the current is measured at a time point t21.

Subsequently, in a similar manner, at a time point tN (note that, here, N is a natural number which satisfies 3≤N≤n), only the N-th switch 210 becomes an ON state in the first switch unit 21. Thus, in response to the first voltage being applied from the first voltage source 201, a current flows through the device under test 10 serving as the test target (here, the N-th device under test 10), and the current is measured at a time point tN1.

### Variation

Although in the above-described embodiment, the second voltage source 23 is described as outputting a voltage of same magnitude as the first voltage source 201, it may output a voltage of different magnitude. Even in this case, since the device under test 10 which is different from the test target can be settled at the predetermined potential and put into the standby state for testing, and a test on each device under test 10 can be started earlier.

In addition, although the second voltage source 23 is described as an amplifier which amplifies the first voltage output from the first voltage source 201, it may be a battery, a rectifier, a converter, or the like which outputs a voltage independently of the first voltage source 201.

In addition, although the constant-voltage generation current measuring unit 20 is described as including, between the first voltage source 201 and the current sensor 203, the amplifier 202 with a gain of 1, it may not include the amplifier 202. In addition, although the first voltage source 201 is described as a battery a rectifier, or a converter, it may include, in addition to these, an amplifier which amplifies its output voltage to the first voltage. A gain of the amplifier provided to the first voltage source 201 may be greater than 1. When the constant-voltage generation current measuring unit 20 does not include the amplifier 202 separately from the first voltage source 201, the current caused to flow through each device under test 10 which is different from the test target by the second voltage source 23 may be greater than the current caused to flow through the device under test 10 serving as the test target by the first voltage source 201. As an example, a wiring resistance of the current path from the second voltage source 23 to each device under test 10 may be smaller than a wiring resistance of the current path from the first voltage source 201 to each device under test 10. Thus, the device under test 10 which is different from the test target can be adjusted to a desired potential immediately and put into the standby state for testing.

In addition, the determination unit 27 is described as determining that, in response to the speed of the change in the measurement value from the current sensor 203 not falling below the reference value within the reference time after the first voltage source 201 starts to apply the voltage to the device under test 10 serving as the test target, this device under test 10 serving as the test target is defective, it may perform a determination by another approach. For example, the determination unit 27 may perform the determination based on the measurement value obtained after the reference time is elapsed after the first voltage source 201 starts to apply the voltage to the device under test 10 serving as the test target. The reference time may be maximum time required, as a result of a preliminary test conducted on the plurality of devices under test 10 in a manufacturing stage of the test apparatuses 2 and 2A, for the potential of the device under test 10 serving as the test target to become stable after the first voltage source 201 starts to apply the voltage to this device under test 10. The reference time may be shorter than time required for a potential of the device under test 10 serving as the test target to become stable after the first voltage source 201 applies a voltage to this device under test 10 when the voltage from the second voltage source 23 is not applied to the device under test 10 which is different from the test target.

In addition, the test systems 1 and 1A may include, as an example of the first measuring unit, instead of the current sensor 203 which measures the value corresponding to the current which flows through the device under test 10 serving as the test target in response to the first voltage being applied from the first voltage source 201, a sensor (a voltage sensor, as an example) which measures a value corresponding to a voltage generated in the device under test 10 serving as the test target in response to a first current of predetermined magnitude flowing from a constant current source. In this case, the test systems 1 and 1A may include the constant current source which outputs the first current instead of the first voltage source 201, and the first switch unit 21 may connect, to the constant current source, the connection terminal 101 of the device under test 10 serving as the test target among the connection terminals 101 of the n devices under test 10. Even in such a case, since the second voltage source 23 outputs the second voltage to the connection terminal 101 of the device under test 10 which is different from the test target of the voltage sensor, the device under test 10 which is different from the test target can be settled at the predetermined potential and put into the standby state for testing.

Various embodiments of the present invention may be described with reference to a flowchart and a block diagram whose block may represent (1) a stage of a process in which an operation is executed or (2) a section of a device responsible for executing the operation. A particular stage and section may be implemented by a dedicated circuit, a programmable circuit supplied together with a computer-readable instruction stored on a computer-readable medium, and/or a processor supplied together with the computer-readable instruction stored on the computer-readable medium. The dedicated circuit may include a digital and/or analog hardware circuit and may include an integrated circuit, or IC, and/or a discrete circuit. The programmable circuit may include a reconfigurable hardware circuit including logical AND, logical OR, logical XOR, logical NAND, logical NOR, and another logical operation, a memory element or the like such as a flip-flop, a register, a field programmable gate array, or FPGA, a programmable logic array, or PLA, or the like.

The computer-readable medium may include any tangible device that may store an instruction to be executed by an appropriate device, and as a result, the computer-readable medium including an instruction stored thereon will include a product including the instruction that may be executed to create means for executing the operation specified in the flowchart or the block diagram. Examples of the computer-readable medium may include an electronic storage medium, a magnetic storage medium, an optical storage medium, an electromagnetic storage medium, a semiconductor storage medium, or the like. More specific examples of the computer-readable medium may include a FLOPPY (registered trademark) disk, a diskette, a hard disk, a random access memory, or RAM, a read-only memory, or ROM, an erasable programmable read-only memory, or EPROM or flash memory, an electrically erasable programmable read-only memory, or EEPROM, a static random access memory, or SRAM, a compact disc read-only memory, or CD-ROM, a digital versatile disk, or DVD, a Blu-ray (registered trademark) disk, a memory stick, an integrated circuit card, or the like.

The computer-readable instruction may include an assembler instruction, an instruction-set-architecture, or ISA instruction, a machine instruction, a machine-dependent instruction, a microcode, a firmware instruction, state-setting data, or either a source code or an object code described in any combination of one or more programming languages, including an object-oriented programming language such as SMALLTALK (registered trademark), JAVA (registered trademark), C++, or the like, and a conventional procedural programming language such as a “C” programming language or a similar programming language.

The computer-readable instruction may be provided for a processor or programmable circuit of a general-purpose computer, special purpose computer, or another programmable data processing device, locally or via a local area network, or LAN, a wide area network, or WAN, such as the Internet, or the like to execute the computer-readable instruction to create means for executing the operation specified in the flowchart or the block diagram. Examples of the processor include a computer processor, a processing unit, a microprocessor, a digital signal processor, a controller, a microcontroller, or the like.

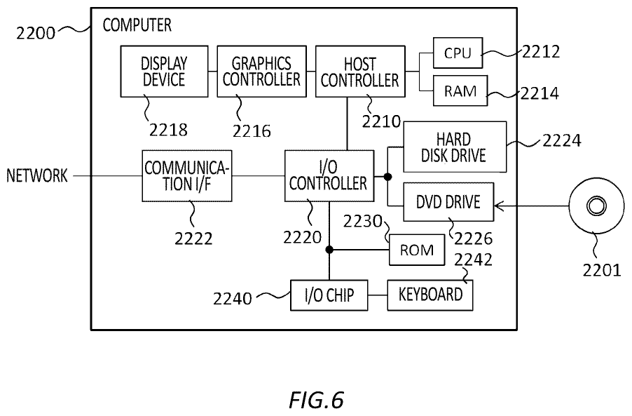

FIG. 6 illustrates an example of a computer 2200 in which a plurality of aspects of the present invention may be embodied entirely or partially. A program installed in the computer 2200 can cause the computer 2200 to function as an operation associated with a device according to the embodiment of the present invention or as one or more sections of the device, or can cause the operation or the one or more sections to be executed, and/or can cause the computer 2200 to execute a process according to the embodiment of the present invention or a stage of the process. Such a program may be executed by a CPU 2212 to cause the computer 2200 to execute a particular operation associated with some or all of the blocks in the flowchart and the block diagram described herein.

The computer 2200 according to the present embodiment includes the CPU 2212, a RAM 2214, a graphics controller 2216, and a display device 2218, which are interconnected by a host controller 2210. The computer 2200 also includes an input/output unit such as a communication interface 2222, a hard disk drive 2224, a DVD-ROM drive 2226, and an IC card drive, which is connected to the host controller 2210 via an input/output controller 2220. The computer also includes a legacy input/output unit such as an ROM 2230 and a keyboard 2242, which is connected to the input/output controller 2220 via an input/output chip 2240.

The CPU 2212 operates according to a program stored in the ROM 2230 and the RAM 2214, thereby controlling each unit. The graphics controller 2216 acquires image data generated by the CPU 2212 in a frame buffer or the like provided in the RAM 2214 or in itself and causes the image data to be displayed on the display device 2218.

The communication interface 2222 communicates with another electronic device via a network. The hard disk drive 2224 stores a program and data used by the CPU 2212 in the computer 2200. The DVD-ROM drive 2226 reads a program or data from a DVD-ROM 2201 and provides the program or the data to the hard disk drive 2224 via the RAM 2214. The IC card drive reads a program and data from the IC card, and/or writes the program and the data to the IC card.

The ROM 2230 stores therein a boot program or the like executed by the computer 2200 at a time of activation, and/or a program which depends on a hardware of the computer 2200. The input/output chip 2240 may also connect various input/output units to the input/output controller 2220 via a parallel port, a serial port, a keyboard port, a mouse port, or the like.

A program is provided by a computer-readable medium such as the DVD-ROM 2201 or the IC card. The program is read from the computer-readable medium, installed in the hard disk drive 2224, the RAM 2214, or the ROM 2230 which is also an example of the computer-readable medium, and executed by the CPU 2212. The information processing described in these kinds of the program is read by the computer 2200, and provides cooperation between the program and the various types of hardware resources described above. A device or method may be configured by achieving an operation or processing of information according to use of the computer 2200.

For example, when communication is executed between the computer 2200 and an external device, the CPU 2212 may execute a communication program loaded in the RAM 2214 and instruct the communication interface 2222 to perform communication processing based on processing described in the communication program. Under control of the CPU 2212, the communication interface 2222 reads transmission data stored in a transmission buffer processing region provided in a recording medium such as the RAM 2214, the hard disk drive 2224, the DVD-ROM 2201, or the IC card, transmits the read transmission data to the network, or writes reception data received from the network in a reception buffer processing region or the like provided on the recording medium.

In addition, the CPU 2212 may cause the RAM 2214 to read all or a necessary part of a file or database stored in an external recording medium such as the hard disk drive 2224, the DVD-ROM drive 2226, or DVD-ROM 2201, the IC card, or the like, and execute various types of processing on data on the RAM 2214. Then, the CPU 2212 writes the processed data back in the external recording medium.

Various types of information such as various types of a program, data, a table, and a database may be stored in the recording medium and subjected to information processing. The CPU 2212 may execute, on the data read from the RAM 2214, various types of processing including various types of an operation, information processing, conditional judgment, conditional branching, unconditional branching, information retrieval/replacement, or the like described throughout the present disclosure and specified by an instruction sequence of the program, and writes a result back to the RAM 2214. In addition, the CPU 2212 may retrieve information in a file, a database, or the like in the recording medium. For example, when a plurality of entries, each having an attribute value of a first attribute associated with an attribute value of a second attribute, is stored in the recording medium, the CPU 2212 may retrieve, out of the plurality of entries, an entry with the attribute value of the first attribute specified which matches a condition, read the attribute value of the second attribute stored in the entry, thereby acquiring the attribute value of the second attribute associated with the first attribute meeting a predetermined condition.

The program or software module described above may be stored in a computer-readable medium on or near the computer 2200. In addition, the recording medium such as a hard disk or a RAM provided in a server system connected to a dedicated communication network or the Internet may be used as a computer-readable medium, thereby providing a program to the computer 2200 via the network.

While the present invention has been described hereinabove by using the embodiment, a technical scope of the present invention is not limited to a scope of the above-described embodiment. It is apparent to persons skilled in the art that various changes or improvements may be made to the embodiment described above. It is also apparent from description of the claims that the embodiment to which such changes or improvements are made can also be included in the technical scope of the present invention.

It should be noted that each process of the operations, procedures, steps, stages, and the like performed by the device, system, program, and method shown in the claims, specification, and drawings may be executed in any order as long as the order is not particularly explicitly indicated by “prior to”, “before”, or the like and as long as an output from a previous process is not used in a later process. Even when the operational flow in the claims, specification, and drawings is described using phrases such as “first”, “next”, or the like for the sake of convenience, it does not necessarily mean that the process must be performed in this order.

### EXPLANATION OF REFERENCES

1: test system;
2: test apparatus;
10: device under test;
20: constant-voltage generation current measuring unit;
21: first switch unit;
23: second voltage source;
24: second switch unit;
25: constant-current generation voltage measuring unit;
26: third switch unit;
27: determination unit;
28: test controller;
101: connection terminal;
201: first voltage source;
202: amplifier;
203: current sensor;
210: switch;
240: switch;
245: wiring;
261: switch;
262: switch;
2200: computer;
2201: DVD-ROM;
2210: host controller;
2212: CPU;
2214: RAM;
2216: graphics controller;
2218: display device;
2220: input/output controller;
2222: communication interface;
2224: hard disk drive;
2226: DVD-ROM drive;
2230: ROM;
2240: input/output chip;
2242: keyboard.

What is claimed is:

1. A test apparatus comprising:
a first power source which outputs a first voltage of predetermined magnitude or a first current of predetermined magnitude;
a first switch unit which connects, to the first power source, a connection terminal of a device under test serving as a test target, among connection terminals of a plurality of devices under test;
a first measuring unit which measures an electrical characteristic of the device under test serving as the test target, in response to the first power source being connected to the device under test serving as the test target; and
a second voltage source which outputs a second voltage of predetermined magnitude to a connection terminal of another at least one device under test which is different from the device under test serving as the test target, among the plurality of devices under test.

2. The test apparatus according to claim 1, wherein a current path between the second voltage source and the another at least one device under test, and a current path between the first power source and the device under test serving as the test target are separate paths from each other.

3. The test apparatus according to claim 1, wherein the second voltage source outputs a voltage concurrently with a measurement by the first measuring unit.

4. The test apparatus according to claim 1, further comprising a second switch unit which selectively connects the second voltage source to the connection terminal of each of the another at least one device under test.

5. The test apparatus according to claim 4, wherein the another at least one device under test comprises a device under test which is to be measured by the first measuring unit subsequent to the device under test serving as the test target, among the plurality of devices under test.

6. The test apparatus according to claim 4, wherein
the first measuring unit measures a value corresponding to a current which flows through the device under test serving as the test target in response to the first voltage being applied from the first power source;
the test apparatus further comprises a second measuring unit which measures, at a different timing from a measurement timing of the first measuring unit, a value corresponding to a voltage generated in a device under test serving as a test target, in response to a current of predetermined magnitude flowing through the device under test serving as the test target,
the second measuring unit is connected between the second voltage source and the second switch unit, and
when the second measuring unit performs a measurement, the second switch unit connects the second measuring unit to a device under test serving as a test target of the second measuring unit.

7. The test apparatus according to claim 1, further comprising a plurality of resistances, each of which is provided in each wiring connecting the second voltage source and each of the connection terminals of the plurality of devices under test.

8. The test apparatus according to claim 7, wherein the first measuring unit adjusts a measurement value measured in a state where the first switch unit connects the device under test serving as the test target to the first power source, according to a measurement value measured in a state where the first switch unit does not connect the device under test serving as the test target to the first power source.

9. The test apparatus according to claim 1, wherein
the first power source outputs the first voltage predetermined, and
the second voltage source is an amplifier which amplifies the first voltage output from the first power source with a preset gain.

10. The test apparatus according to claim 2, wherein
the first power source outputs the first voltage predetermined, and
the second voltage source is an amplifier which amplifies the first voltage output from the first power source with a preset gain.

11. The test apparatus according to claim 3, wherein
the first power source outputs the first voltage predetermined, and
the second voltage source is an amplifier which amplifies the first voltage output from the first power source with a preset gain.

12. The test apparatus according to claim 4, wherein
the first power source outputs the first voltage predetermined, and
the second voltage source is an amplifier which amplifies the first voltage output from the first power source with a preset gain.

13. The test apparatus according to claim 5, wherein
the first power source outputs the first voltage predetermined, and
the second voltage source is an amplifier which amplifies the first voltage output from the first power source with a preset gain.

14. The test apparatus according to claim 6, wherein
the first power source outputs the first voltage predetermined, and
the second voltage source is an amplifier which amplifies the first voltage output from the first power source with a preset gain.

15. The test apparatus according to claim 1, wherein
the first power source outputs the first voltage predetermined, and
the second voltage is a voltage of a same magnitude as the first voltage.

16. The test apparatus according to claim 1, wherein
the first power source outputs the first voltage predetermined, and
the second voltage is a voltage which is closer to the first voltage than to a ground voltage of the plurality of devices under test.

17. The test apparatus according to claim 1, wherein a current that the second voltage source causes to flow through the another at least one device under test is greater than a current that the first power source causes to flow through the device under test serving as the test target.

18. The test apparatus according to claim 1, further comprising:
a determination unit which determines quality of the device under test serving as the test target, based on a measurement result from the first measuring unit, wherein
the determination unit determines the device under test serving as the test target to be defective in response to a speed of change in a value of the measurement result from the first measuring unit not falling below a reference value within a reference time after the first power source is connected to the device under test serving as the test target.

19. The test apparatus according to claim 1, wherein the first measuring unit measures a value corresponding to a current which flows through the device under test serving as the test target in response to the first power source applying the first voltage, or measures a value corresponding to a voltage generated in the device under test serving as the test target in response to the first current flowing from the first power source.

20. A test method comprising:
connecting a connection terminal of a device under test serving as a test target among connection terminals of a plurality of devices under test to a first power source which outputs a first voltage of predetermined magnitude or a first current of predetermined magnitude, and applying, from a second voltage source, a second voltage of predetermined magnitude to a connection terminal of another at least one device under test which is different from the device under test serving as the test target among the plurality of devices under test, and
measuring an electrical characteristic of the device under test serving as the test target in response to the first power source being connected to the device under test serving as the test target.
